(19) United States
(12) Patent Application Publication
(10) Pub. No.: US 2024/0186290 A1
(43) Pub. Date: Jun. 6, 2024

(54) SEMICONDUCTOR PACKAGE

(71) Applicant: SAMSUNG ELECTRONICS CO., LTD., Suwon-si (JP)

(72) Inventors: Taehwan KIM, Suwon-si (KR); Youngdeuk KIM, Suwon-si (KR); Jaechoon KIM, Suwon-si (KR); Kyungsuk OH, Suwon-si (KR); Jonggyu LEE, Suwon-si (KR); Mina CHOI, Suwon-si (KR)

(21) Appl. No.: 18/236,024

(22) Filed: Aug. 21, 2023

(30) Foreign Application Priority Data
Dec. 2, 2022 (KR) 10-2022-0166926

(51) Int. Cl. H01L 25/065; H01L 23/00; H01L 23/31; H01L 23/48; H01L 23/522

(52) U.S. Cl. CPC H01L 25/0657; H01L 23/3128; H01L 23/481; H01L 23/5226; H01L 24/16; H01L 24/17; H01L 24/32; H01L 24/33; H01L 24/73; H01L 2224/16145; H01L 2224/17181; H01L 2224/32145; H01L 2224/33181; H01L 2224/73204; H01L 2224/73253; H01L 2225/06513; H01L 2225/06541

(57) ABSTRACT

A semiconductor package includes electrically connected first to third semiconductor chips, stacked in a vertical direction; an encapsulant on the first semiconductor chip and encapsulating a portion of each of the semiconductor chips; and external connection bumps below the first semiconductor chip and being electrically connected to the semiconductor chips, wherein the semiconductor chips each include a plurality of lower pads, the first and second semiconductor chips each include a plurality of upper pads including a first group of upper pads and a second group of upper pads, and through-electrodes electrically respectively connecting the upper pads and the lower pads, and the through-electrodes include a first group of through-electrodes respectively connected to the first group of upper pads, and a second group of through-electrodes connected to upper pads that are electrically connected to each other of the second group of upper pads.

### CROSS-REFERENCE TO RELATED APPLICATION

This application claims the priority and benefit of Korean Patent Application No. 10-2022-0166926, filed on Dec. 2, 2022, with the Korean Intellectual Property Office, which is incorporated herein by reference.

### BACKGROUND

### 1. Field

Embodiments relate to a semiconductor package.

### 2. Description of the Related Art

In accordance with weight reductions and the implementation of high performance in electronic devices, miniaturized and high-performance semiconductor packages may be used in the field of semiconductor packages. In order to realize miniaturization, weight reductions, high performance, and high reliability of a semiconductor package, a semiconductor package having a structure in which semiconductor chips are stacked in multiple stages has been considered.

### SUMMARY

The embodiments may be realized by providing a semiconductor package including a first semiconductor chip, at least one second semiconductor chip, and a third semiconductor chip, sequentially stacked in a vertical direction and electrically connected to each other; an encapsulant on the first semiconductor chip, the encapsulant encapsulating at least a portion of each of the first semiconductor chip, the at least one second semiconductor chip, and the third semiconductor chip; and a plurality of external connection bumps below the first semiconductor chip, the plurality of external connection bumps being electrically connected to the first semiconductor chip, the at least one second semiconductor chip, and the third semiconductor chip, wherein the first semiconductor chip, the at least one second semiconductor chip, and the third semiconductor chip each include a plurality of lower pads, the first semiconductor chip and the at least one second semiconductor chip each include a plurality of upper pads including a first group of upper pads and a second group of upper pads, and a plurality of through-electrodes electrically respectively connecting the plurality of upper pads and the plurality of lower pads, and the plurality of through-electrodes includes a first group of through-electrodes respectively connected to the first group of upper pads, and a second group of through-electrodes connected to upper pads that are electrically connected to each other of the second group of upper pads.

The embodiments may be realized by providing a semiconductor package including a first semiconductor chip including a first group of through-electrodes, a second group of through-electrode around the first group of through-electrodes, a first group of upper pads electrically connected to the first group of through-electrodes, and a second group of upper pads electrically connected to the second group of through-electrodes; a second semiconductor chip on the first semiconductor chip, the second semiconductor chip including a first group of lower pads electrically connected to the first group of upper pads and a second group of lower pads electrically connected to the second group of lower pads; and a plurality of interconnection bumps between the first semiconductor chip and the second semiconductor chip, the plurality of interconnection bumps electrically connecting corresponding ones of the first group of upper pads and the first group of lower pads and corresponding ones of the second group of upper pads and the second group of lower pads, wherein upper pads of the second group of upper pads, that are connected to each other, are connected to one through-electrode of the second group of through-electrodes.

The embodiments may be realized by providing a semiconductor package including a plurality of semiconductor chips stacked in a vertical direction, wherein at least one semiconductor chip among the plurality of semiconductor chips includes a substrate, a plurality of lower pads below the substrate, a plurality of upper pads on the substrate, and a plurality of through-electrodes penetrating through the substrate and electrically connected to at least one of the plurality of lower pads and the plurality of upper pads, and the plurality of through-electrodes includes a first group of through-electrodes connected to one upper pad among the plurality of upper pads, and a second group of through-electrodes connected to two or more upper pads among the plurality of upper pads.

### BRIEF DESCRIPTION OF DRAWINGS

Features will be apparent to those of skill in the art by describing in detail exemplary embodiments with reference to the attached drawings in which:

FIG. 1 is a cross-sectional view illustrating a semiconductor package according to an example embodiment.

FIG. 2A is a partially enlarged view of region ‘A’ in FIG. 1, and FIG. 2B is a partially enlarged view of a region corresponding to FIG. 2A in a modified semiconductor package.

FIG. 3A is a plan view illustrating a cross-section taken along line I-I′ of FIG. 2A, and FIGS. 3B and 3C are plan views illustrating a region corresponding to FIG. 3A in a modified example semiconductor package.

FIG. 4A is a cross-sectional view illustrating a semiconductor package according to an example embodiment, and FIG. 4B is a partially enlarged view illustrating region ‘B’ of FIG. 4A.

FIG. 5A is a plan view illustrating a cross-section taken along line II-II′ of FIG. 4B, and FIGS. 5B and 5C are plan views illustrating a region corresponding to FIG. 5A in a modified semiconductor package.

FIG. 6A is a cross-sectional view illustrating a semiconductor package according to an example embodiment, and FIG. 6B is a partially enlarged view illustrating region ‘C’ of FIG. 6A.

FIG. 7A is a cross-sectional view illustrating a semiconductor package according to an example embodiment, and FIG. 7B is a partially enlarged view illustrating region ‘D’ of FIG. 7A.

FIG. 8 is a cross-sectional view illustrating a semiconductor package according to an example embodiment.

FIG. 9 is a cross-sectional view illustrating a semiconductor package according to an example embodiment.

### DETAILED DESCRIPTION

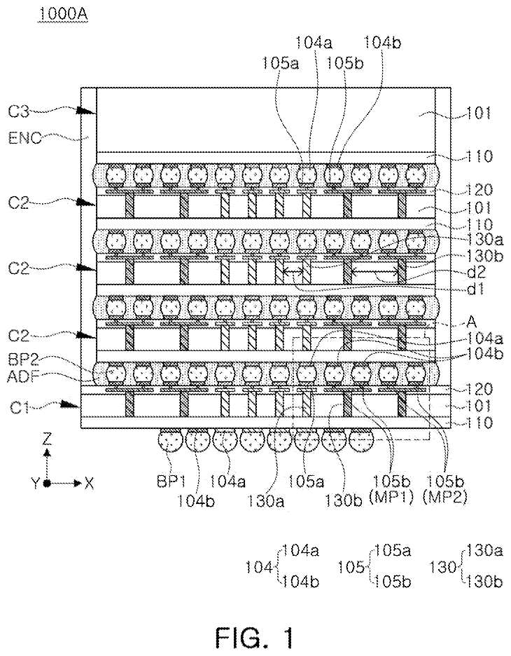

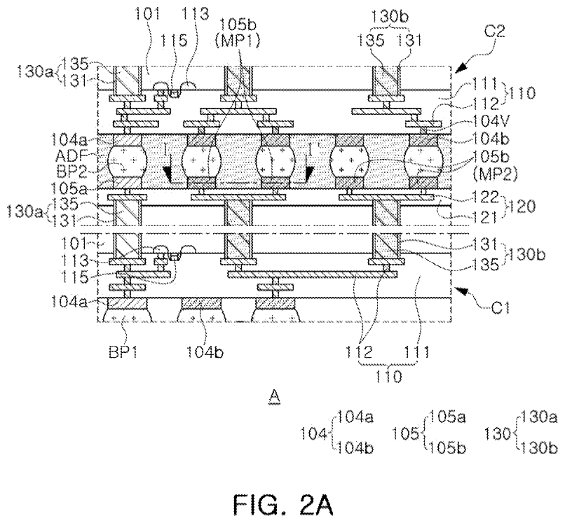

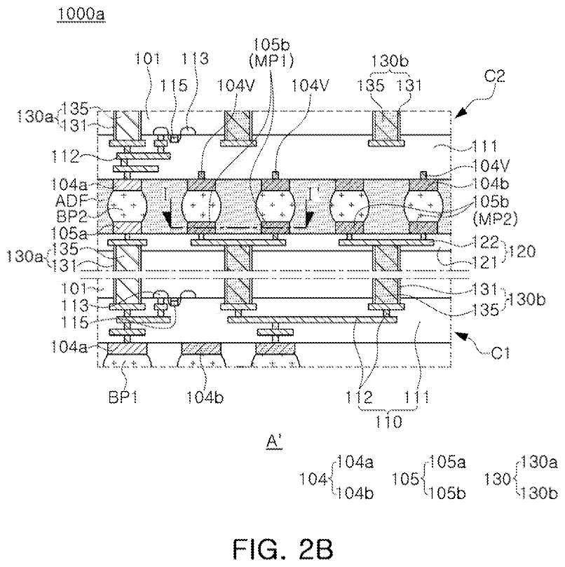

FIG. 1 is a cross-sectional view illustrating a semiconductor package 1000A according to an example embodiment, FIG. 2A is a partially enlarged view of region ‘A’ in FIG. 1, and FIG. 2B is a partially enlarged view illustrating a region corresponding to FIG. 2A in a modified semiconductor package.

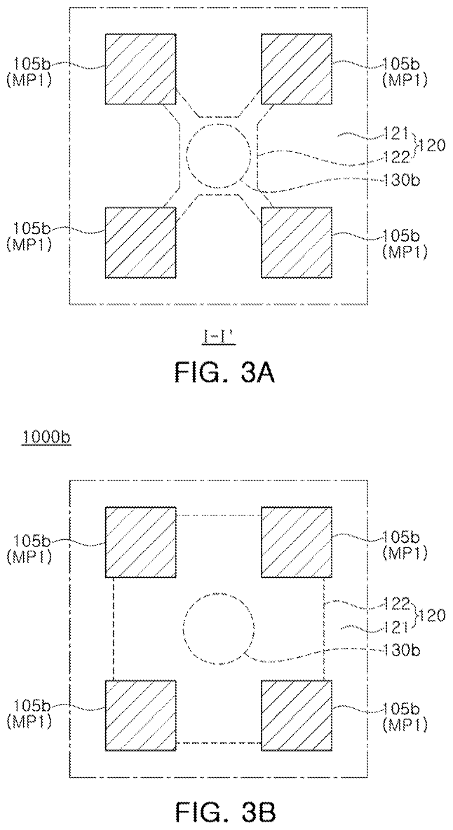

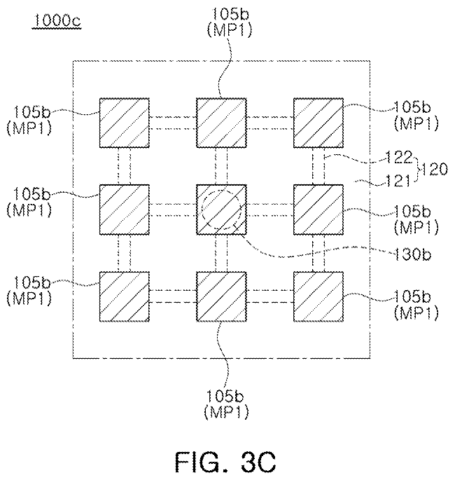

FIG. 3A is a plan view illustrating a cross-section taken along line I-I′ of FIG. 2A, and FIGS. 3B and 3C are plan views illustrating a region corresponding to FIG. 3A in a modified example semiconductor package.

Referring to FIGS. 1, 2A, and 3A, the semiconductor package 1000A according to an example embodiment may include a plurality of semiconductor chips C1, C2, and C3, stacked in a vertical direction (Z direction). The plurality of semiconductor chips C1, C2, and C3 may be electrically connected to each other through a plurality of through-electrodes 130. In an implementation, the semiconductor package 1000A may further include an encapsulant ENC and a plurality of external connection bumps BP1.

In an implementation, heat dissipation characteristics of the semiconductor package 1000A may be improved by introducing dummy electrodes forming a heat dissipation path in a stacking direction of the plurality of semiconductor chips C1, C2, and C3. In addition, by connecting one dummy electrode to two or more dummy pads, process difficulty and manufacturing costs may be reduced, and production yield may be secured. In an implementation, the plurality of through-electrodes 130 may include a first group of through-electrodes 130a, each connected to one upper pad 105a among the plurality of upper pads 105, and a second group of through-electrodes 130b, each connected to two or more upper pads 105b among the plurality of upper pads 105. As used herein, the terms “first,” “second,” and the like are merely for identification and differentiation, and are not intended to imply or require sequential inclusion (e.g., a third element and a fourth element may be described without implying or requiring the presence of a first element or second element).

The plurality of semiconductor chips C1, C2, and C3 may each include a substrate 101, a lower interconnection structure 110, an upper interconnection structure 120, or a plurality of through-electrodes 130, respectively. In an implementation, the uppermost semiconductor chip (or ‘third semiconductor chip C3’) may not include an upper interconnection structure 120 and a plurality of through-electrodes 130. As used herein, the term “or” is not an exclusive term, e.g., “A or B” would include A, B, or A and B.

The substrate 101 may include, e.g., a semiconductor element such as silicon or germanium (Ge), or may include a compound semiconductor such as silicon carbide (SiC), gallium arsenide (GaAs), indium arsenide (InAs), or indium phosphide (InP). The substrate 101 may have a silicon-on-insulator (SOI) structure. The substrate 101 may include a conductive region 113, e.g., a well doped with impurities, a structure doped with impurities, and various device isolation structures such as a shallow trench isolation (STI) structure. Individual devices 115 constituting an integrated circuit may be on an active surface of the substrate 101 on which the conductive region 113 is formed. The conductive region 113 and the individual devices 115 may be electrically connected to the plurality of through-electrodes 130 or the plurality of lower pads 104 through the lower interconnection layer 112. The individual devices 115 may include, e.g., a field effect transistor (FET) such as planar FET or FinFET, memory devices such as a flash memory, dynamic random access memory (DRAM), static random access memory (SRAM), electrically erasable programmable read-only memory (EEPROM), phase-change random access memory (PRAM), magnetoresistive random access memory (MRAM), ferroelectric random access memory (FeRAM), resistive random access memory (RRAM), logic devices such as AND, OR, NOT, or various active devices or passive devices such as system large scale integration (LSI), a CMOS imaging sensor (CIS), or a microelectromechanical system (MEMS).

The lower interconnection structure 110 may be on one surface (e.g., active surface) of the substrate 101, and may include a lower insulating layer 111 and a lower interconnection layer 112. The lower insulating layer 111 may include, e.g., Flowable Oxide (FOX), Tonen SilaZen (TOSZ), Undoped Silica Glass (USG), Borosilica Glass (BSG), PhosphoSilaca Glass (PSG), BoroPhosphoSilica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide, or a combination thereof. At least a portion of the lower insulating layer 111 surrounding the lower interconnection layer 112 may include a low dielectric layer. The lower insulating layer 111 may be formed using a chemical vapor deposition (CVD) process, a flowable-CVD process, or a spin coating process.

The lower interconnection layer 112 may be between a plurality of lower pads 104 and a plurality of through-electrodes 130, and may be buried in the lower insulating layer 111. The lower interconnection layer 112 may have a multilayer structure including interconnection patterns and vias including, e.g., aluminum (Al), gold (Au), cobalt (Co), copper (Cu), nickel (Ni), lead (Pb), tantalum (Ta), tellurium (Te), titanium (Ti), tungsten (W), or a combination thereof. A barrier film including titanium (Ti), titanium nitride (TiN), tantalum (Ta), or tantalum nitride (TaN) may be between the interconnection patterns or vias and the lower insulating layer 111. The lower interconnection layer 112 may connect the individual devices 115 to each other, to the conductive region 113, or to the plurality of lower pads 104.

The plurality of lower pads 104 may be below the substrate 101 and the lower interconnection structure 110. The plurality of lower pads 104 may include a metal material, similar to that of the lower interconnection layer 112. In an implementation, the plurality of lower pads 104 may include aluminum (Al), copper (Cu), nickel (Ni), tungsten (W), platinum (Pt), or gold (Au). The plurality of lower pads 104 may include a first group of lower pads 104a and a second group of lower pads 104b. The first group of lower pads 104a may include a signal pad, a power pad, and a ground pad, and the second group of lower pads 104b may include a heat-dissipation dummy pad. The first group of lower pads 104a may be electrically connected to the first group of upper pads 105a, facing each other, and the second group of lower pads 104b may be electrically connected to the second group of upper pads 105b, facing each other. The first group of lower pads 104a may be electrically connected to the first group of through-electrodes 130a through the lower interconnection layer 112. The second group of lower pads 104b may be electrically connected to the second group of through-electrodes 130b through the lower interconnection layer 112.

In an implementation, the second group of lower pads 104b may be electrically insulated from the lower interconnection layer 112. In an implementation, the second group of lower pads 104b may be electrically insulated from the through-electrodes 130b, or may be electrically insulated from the lower interconnection layer 112. In an implementation, as illustrated in FIG. 2B, in the semiconductor package 1000a of a modified example, at least one semiconductor chip (e.g., ‘second semiconductor chip C2’) may further include a lower interconnection layer 112 and a lower insulating layer 111 covering the lower interconnection layer 112, and the second group of lower pads 104b may include a via portion 104V extending into the lower insulating layer 111.

As described above, the lower pads 104b facing the upper pads MP1 or MP2 electrically connected to each other may include a via portion 104V extending into the lower insulating layer 111, so that a heat-dissipation path, blocked by the lower insulating layer 111 may extend upwardly.

The upper interconnection structure 120 may be on the other surface of the substrate 101 (e.g., a surface opposite to the active surface), and may include an upper insulating layer 121 and an upper interconnection layer 122. The upper insulating layer 121 may include a material, similar to that of the lower insulating layer 111. In an implementation, at least a portion of the upper insulating layer 121 surrounding the upper interconnection layer 122 may include a low dielectric layer. The upper insulating layer 121 may be formed using a chemical vapor deposition (CVD) process, a flowable-CVD process, or a spin coating process.

The upper interconnection layer 122 may be between the plurality of upper pads 105 and the plurality of through-electrodes 130, and may be buried in the upper insulating layer 121. The upper interconnection layer 122 may include a material similar to that of the lower interconnection layer 112. The upper interconnection layer 122 may have a multilayer structure including interconnection patterns and vias.

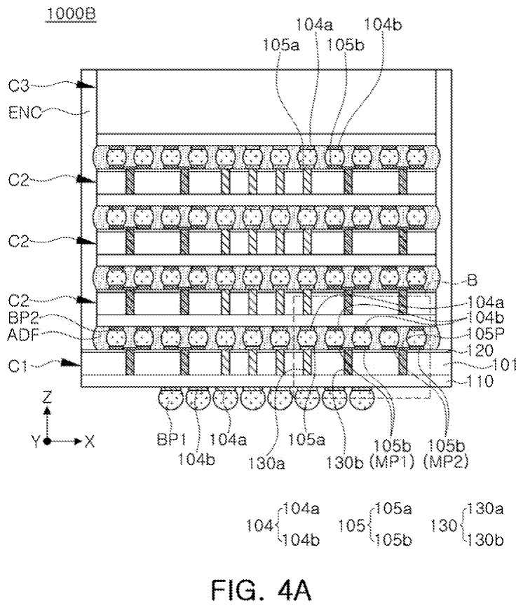

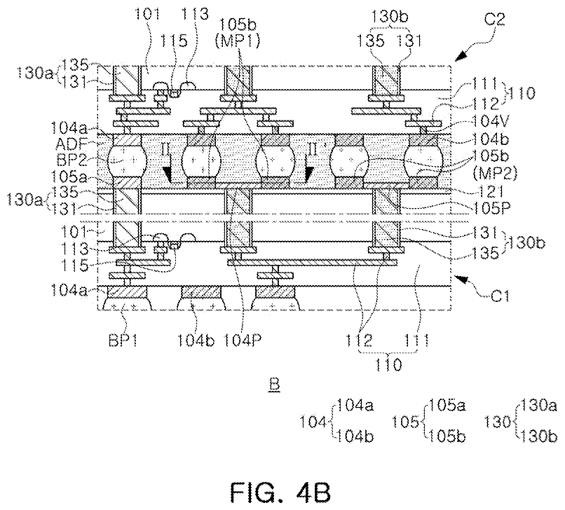

In an implementation, the plurality of upper pads 105 may include, e.g., aluminum (Al), copper (Cu), nickel (Ni), tungsten (W), platinum (Pt), or gold (Au). The plurality of upper pads 105 may include a first group of upper pads 105a and a second group of upper pads 105b. The first group of upper pads 105a may include a signal pad, a power pad, and a ground pad, and the second group of upper pads 105b may include a dummy heat dissipation pad. The first group of upper pads 105a may be electrically connected to the first group of through-electrodes 130a through the upper interconnection layer 122. The second group of upper pads 105b may be electrically connected to the second group of through-electrodes 130b through the upper interconnection layer 122. In an implementation, the upper interconnection layer 122 may be omitted (see FIGS. 4A and 4B). Each of the first group of upper pads 105a may be connected to one of the first group of through-electrodes 130a. Upper pads MP1 or MP2 electrically connected to each other, among the second group of upper pads 105b, may be connected to one of the second group of through-electrodes 130b.

The second group of upper pads 105b may be arranged in a matrix on the substrate 101 and the upper interconnection structure 120. On a plane, e.g., in a plan view, the upper pads MP1 or MP2, connected to each other, among the second group of upper pads 105b may be arranged in a predetermined matrix form, and one through-electrode among the second group of through-electrodes 130b, connected to the upper pads MP1 or MP2, connected to each other, may be in a center of the matrix. As illustrated in FIG. 3A, upper pads MP1 connected to each other may be arranged in a 2×2 matrix. In an implementation, one through-electrode of the second group of through-electrodes 130b may be at a center of the matrix, spaced apart from the upper pads MP1 by the same distance. The upper interconnection layer 122 may radially extend from the second group of through-electrode 130b to each of the upper pads MP1. In an implementation, a dispositional form of the upper pads MP1 and a shape of the upper interconnection layer 122 may be variously modified.

In an implementation, as illustrated in FIG. 3B, in the semiconductor package 1000b of a modified example, the upper pads MP1 may be arranged in a 2×2 matrix, and the upper interconnection layer 122 connecting the same may have a plate shape, overlapping at least a portion of each of the upper pads MP1 and the second group of through-electrodes 130b.

In an implementation, as illustrated in FIG. 3C, in the semiconductor package 1000c of a modified example, the upper pads MP1 may be arranged in a 3×3 matrix. The second group of through-electrodes 130b may overlap upper pads 105b in the center of the upper pads MP1. The upper interconnection layer 122 may extend in a mesh shape between adjacent upper pads MP1.

The plurality of through-electrodes 130 may penetrate through the substrate 101, and may be electrically connected to at least a portion or some of the plurality of lower pads 104 and to at least a portion or some of the plurality of upper pads 105. The plurality of through-electrodes 130 may include a via plug 135 and a side barrier film 131 surrounding a side surface of the via plug 135. The via plug 135 may include, e.g., tungsten (W), titanium (Ti), aluminum (Al), or copper (Cu), and may be formed through a plating process, a PVD process, or a CVD process. The side barrier film 131 may include titanium (Ti), titanium nitride (TiN), tantalum (Ta), or tantalum nitride (TaN), and may be formed by a plating process, a PVD process, or a CVD process. In an implementation, a side insulating film including an insulating material (e.g., a high aspect process (HARP) oxide) such as silicon oxide, silicon nitride, or silicon oxynitride may be between the side barrier film 131 and the substrate 101.

The plurality of through-electrodes 130 may include a first group of through-electrodes 130a and a second group of through-electrodes 130b. In an implementation, on a plane (XY plane), the first group of through-electrodes 130a and the second group of through-electrodes 130b may be aligned on the same line in one direction (e.g., X direction). In an implementation, on a plane, the first group of through-electrodes 130a and the second group of through-electrodes 130b may be aligned on different reference lines in one direction (e.g., X direction).

The first group of through-electrodes 130a may be respectively connected to the first group of upper pads 105a through the upper interconnection layer 122. The first group of through-electrodes 130a may be connected to the first group of lower pads 104a by the lower interconnection layer 112. In an implementation, two or more first group of through-electrodes 130a may be merged and connected to one first group of lower pad 104a. The first group of through-electrodes 130a may include signal electrodes, power electrodes, and ground electrodes.

The second group of through-electrodes 130b may be connected to upper pads MP1 and MP2, electrically connected to each other, among the second group of upper pads 105b by the upper interconnection layer 122. The second group of through-electrodes 130b may be connected to at least one of the second group of lower pads 104b by the lower interconnection layer 112. In an implementation, two or more of the second group of through-electrodes 130b may be merged or connected to only one of the second group of lower pads 104b. In an implementation, widths of electrodes of the second group of through-electrodes 130b may be greater than widths of electrodes of the first group of through-electrodes 130a. The second group of through-electrodes 130b may include a dummy electrode for heat dissipation.

The second group of through-electrodes 130b may be around the first group of through-electrodes 130a, and may be electrically insulated from the first group of through-electrodes 130a. A separation distance d2 between electrodes of the second group of through-electrodes 130b may be equal to or greater than a separation distance d1 between electrodes of the first group of through-electrodes 130a. In an implementation, the separation distance d1 between electrodes of the first group of through-electrodes 130a may be in a range of about 1 μm to about 30 μm, about 4 μm to about 30 μm, or about 4 μm to about 25 μm, and the separation distance d2 between electrodes of the second group of through-electrodes 130b may be in a range of about 40 μm or less, or about 30 μm or less. In an implementation, one electrode of the second group of through-electrodes 130b may be connected to the upper pads MP1 or MP2, electrically connected to each other, thereby reducing process difficulty and manufacturing costs, while securing a heat dissipation path.

The plurality of semiconductor chips C1, C2, and C3 may include a first semiconductor chip C1 (‘lowermost semiconductor chip’), at least one second semiconductor chip C2, and a third semiconductor chip (‘uppermost semiconductor chip’), sequentially stacked on the first semiconductor chip C1.

The first semiconductor chip C1 may be, e.g., a buffer chip including a plurality of logic devices and/or memory devices on the lower interconnection structure 110. In an implementation, the first semiconductor chip C1 may transmit a signal from the second semiconductor chip C2 and the third semiconductor chip C2, stacked thereabove externally, and also transmit a signal and power from the outside to the second semiconductor chip C2 and the third semiconductor chip C3. The first semiconductor chip 100 may perform both a logic function and a memory function through logic devices and memory devices, but may include only logic devices and perform only a logic function according to example embodiments. The first semiconductor chip C1 may have a width greater than a width of at least one of the second semiconductor chip C2 and a width of the third semiconductor chip C3. The second group of through-electrodes 130b of the first semiconductor chip C1 may be electrically connected to at least one of the plurality of external connection bumps BP1 by the lower interconnection layer 112.

The second semiconductor chip C2 and the third semiconductor chip C3 may include memory chips or memory devices storing data based on an address command, a control command, or the like, received from the first semiconductor chip C1, and outputting the same. In an implementation, the second semiconductor chip C2 and the third semiconductor chip C3 may include volatile memory devices such as DRAM and SRAM or non-volatile memory devices such as PRAM, MRAM, FeRAM, and RRAM.

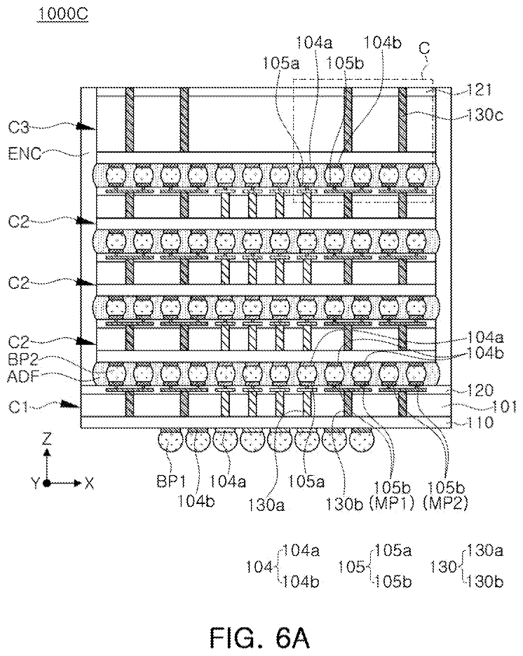

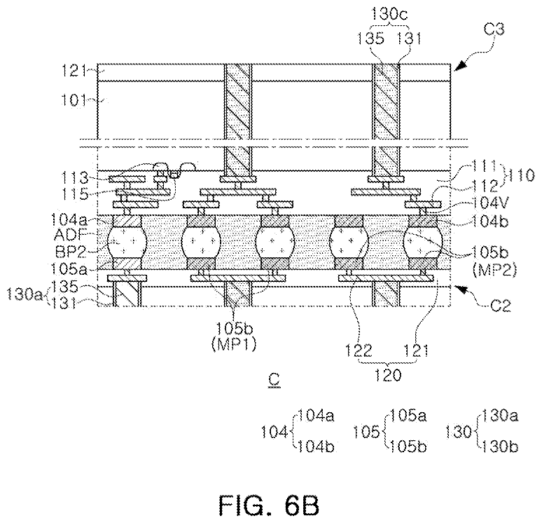

The width of the second semiconductor chip C2 and the width of the third semiconductor chip C3 may be substantially the same. The third semiconductor chip C3 may not include the through electrode 130, and may have an upper surface thereof exposed from (e.g., not covered by) the encapsulant ENC. In an implementation, the third semiconductor chip C3 may include dummy electrodes penetrating through the substrate 101 (see example embodiments of FIGS. 6A and 6B).

The plurality of semiconductor chips C1, C2, and C3 may be electrically connected to a plurality of interconnection bumps BP2. The plurality of interconnection bumps BP2 may be between the first semiconductor chip C1, the second semiconductor chip C2, and the third semiconductor chip C3, and may be electrically connected to the plurality of through-electrodes 130. In an implementation, the plurality of interconnection bumps BP2 may be between the first semiconductor chip C1, the second semiconductor chip C2, and the third semiconductor chip C3, and may electrically connect the first group of upper pads 105a and the first group of lower pads 104a, to the second group of upper pads 105b and the second group of lower pads 104b, corresponding to (e.g., facing or aligned with) each other. The plurality of interconnection bumps BP2 may include, e.g., tin (Sn) or an alloy containing tin (Sn) (e.g., Sn—Ag—Cu). In an implementation, the plurality of interconnection bumps BP2 may include a combination of a metal pillar and a solder ball.

A plurality of adhesive films ADF may surround the plurality of interconnection bumps BP2, and fix the plurality of semiconductor chips C1, C2, and C3. In an implementation, the plurality of adhesive films ADF may surround a plurality of interconnection bumps BP2 between the first semiconductor chip C1, the second semiconductor chip C2, and the third semiconductor chip C3. The plurality of adhesive films ADF may be non-conductive films (NCFs), and may include, e.g. suitable polymer films capable of thermal compression bonding.

The encapsulant ENC may be on the first semiconductor chip C1, and may encapsulate at least a portion of each of the first semiconductor chip C1, the second semiconductor chip C2, and the third semiconductor chip C3. The encapsulant ENC may surround side surfaces of the second semiconductor chip C2 and the third semiconductor chip C3. The encapsulant ENC may expose an upper surface of the third semiconductor chip C3. In an implementation, the encapsulant ENC may cover the upper surface of the third semiconductor chip C3. In an implementation, the encapsulant ENC may be formed of, e.g., an insulating material such as an epoxy mold compound (EMC).

The plurality of external connection bumps BP1 may be below the first semiconductor chip C1, and may be electrically connected to the first semiconductor chip C1, the second semiconductor chip C2, and the third semiconductor chip C3. The plurality of external connection bumps BP1 may include, e.g., tin (Sn) or an alloy containing tin (Sn) (e.g., Sn—Ag—Cu). In an implementation, the plurality of external connection bumps BP1 may include a combination of a metal pillar and a solder ball. The plurality of external connection bumps BP1 may be electrically connected to external devices such as a module substrate, a system board, and the like.

FIG. 4A is a cross-sectional view of a semiconductor package 1000B according to an example embodiment, and FIG. 4B is a partially enlarged view of region ‘B’ of FIG. 4A.

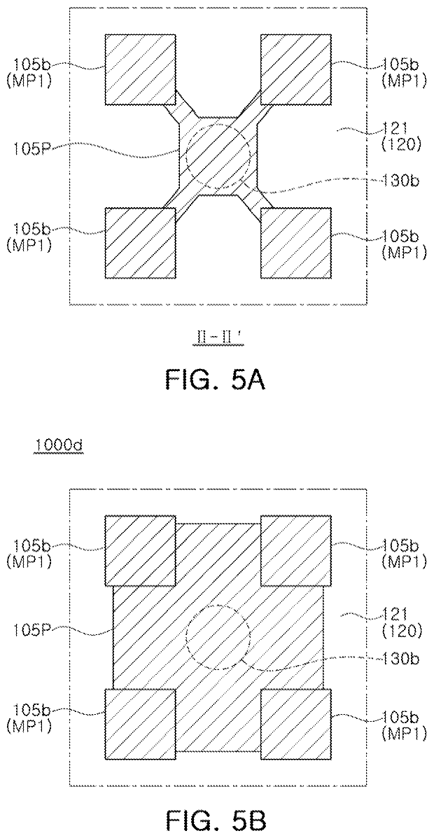

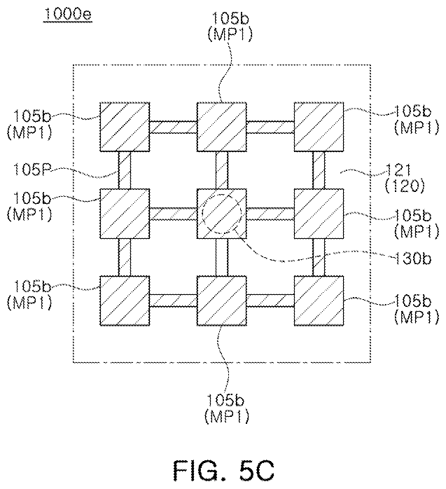

FIG. 5A is a plan view illustrating a cross-section taken along line II-II′ of FIG. 4B, and FIGS. 5B and 5C are plan views illustrating a region corresponding to FIG. 5A in a modified semiconductor package.

Referring to FIGS. 4A, 4B, and 5A, the semiconductor package 1000B according to an example embodiment may have the same or similar characteristics as those described with reference to FIGS. 1 to 3C, except that the second group of upper pads 105b may be connected by a pattern portion 105P.

In an implementation, the first semiconductor chip C1 and the second semiconductor chip C2 may include an upper insulating layer 121 surrounding upper portions of the plurality of through-electrodes 130 and on which a plurality of upper pads 105 are disposed, and a pattern portion 105P on the upper insulating layer 121 and extending between upper pads MP1 and MP2 electrically connected to each other.

The second group of through-electrodes 130b may be connected to the upper pads MP1 or MP2 electrically connected to each other by the pattern portion 105P. The pattern portion 105P may extend along a surface of the upper insulating layer 121 between the second group of upper pads 105b. The pattern portion 105P may include a material, similar to that of the plurality of upper pads 105. In an implementation, in the pattern portion 105P, the plurality of upper pads 105 may include aluminum (Al), copper (Cu), nickel (Ni), tungsten (W), platinum (Pt), or gold (Au). In an implementation, the pattern portion 105P may be integrally formed with the adjacent second group of upper pads 105b. The pattern portion 105P may connect one of the second group of through-electrodes 130b to the plurality of upper pads 105. The pattern portion 105P may be connected to one electrode of the second group of through-electrodes 130b, so that process difficulty and manufacturing costs may be reduced, and production yield may be secured, while securing a heat dissipation path through the second group of through-electrodes 130b and the upper pads MP1 or MP2, connected to each other.

In an implementation, an upper interconnection layer 122 connecting the plurality of through-electrodes 130 and the plurality of upper pads 105 may be omitted. In an implementation, the upper interconnection structure 120 may include an upper interconnection layer 122, but the upper interconnection layer 122 may not be formed between the second group of through-electrodes 130b and the pattern portion 105P, or the second group of through-electrodes 130b may be connected to the pattern portion 105P through the upper interconnection layer 122.

As illustrated in FIG. 5A, the upper pads MP1, connected to each other may be arranged in a 2×2 matrix, and the pattern portion 105P may extend radially from the second group of through-electrodes 130b to each of the upper pads MP1. In an implementation, a dispositional form of the upper pads MP1 and the shape of the upper interconnection layer 122 may be variously modified.

In an implementation, as illustrated in FIG. 5B, in the semiconductor package 1000d of a modified example, the upper pads MP1 may be arranged in a 2×2 matrix, and the pattern portion 105P connecting the upper pads MP1 may have a plate shape overlapping at least a portion of each of the upper pads MP1 and the second group of through-electrodes 130b.

In an implementation, as illustrated in FIG. 5C, in the semiconductor package 1000e of a modified example, the upper pads MP1 may be arranged in a 3×3 matrix. The second group of through-electrodes 130b may overlap the upper pad 105b in a center of the upper pads MP1. The pattern portion 105P may extend in a mesh shape between adjacent upper pads MP1.

FIG. 6A is a cross-sectional view illustrating a semiconductor package 1000C according to an example embodiment, and FIG. 6B is a partially enlarged view illustrating region ‘C’ of FIG. 6A.

Referring to FIGS. 6A and 6B, the semiconductor package 1000C according to an example embodiment may have the same or similar characteristics as those described with reference to FIGS. 1 to 5C, except for further including dummy electrodes 130c exposed on the third semiconductor chip C3.

In an implementation, the third semiconductor chip C3 may further include dummy electrodes 130c each having one end electrically connected to the second group of lower pads 104b and another end exposed at an upper surface of the third semiconductor chip C3 or an upper insulating layer 121 surrounding upper portions of the dummy electrodes 130c.

The dummy electrodes 130c may have characteristics substantially the same as or similar to those of the second group of through-electrodes 130b. The dummy electrodes 130c may each be connected to at least one pad of the second group of lower pads 104b by the lower interconnection layer 112. In an implementation, two or more dummy electrodes 130c may be merged and connected to only one pad of the second group of lower pads 104b. In an implementation, widths of the dummy electrodes 130c may be greater than widths of the first group of through-electrodes 130a. A separation distance between the dummy electrodes 130c may be greater than a separation distance between the first group of through-electrodes 130a. In an implementation, heat dissipation characteristics may be improved, by introducing the dummy electrodes 130c, extending to an upper portion of the uppermost semiconductor chip (′ third semiconductor chip C3′).

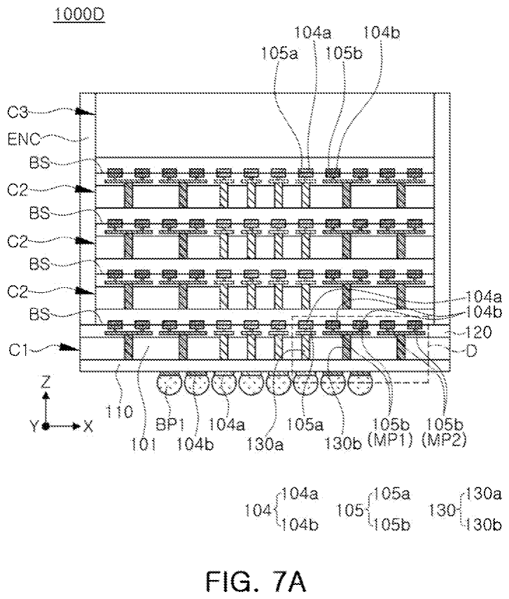

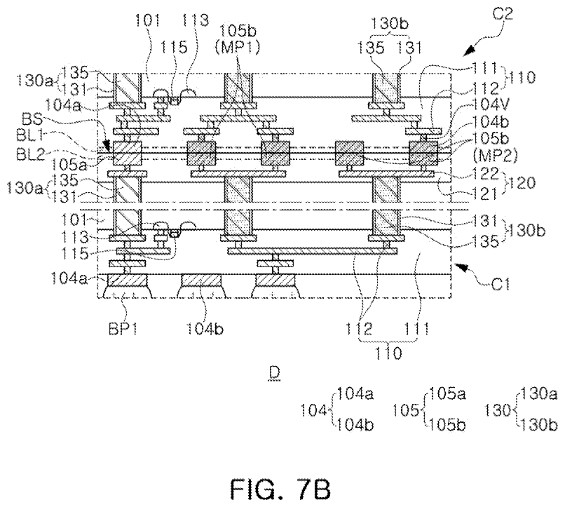

FIG. 7A is a cross-sectional view illustrating a semiconductor package 1000D according to an example embodiment, and FIG. 7B is a partially enlarged view illustrating region ‘D’ of FIG. 7A.

Referring to FIGS. 7A and 7B, the semiconductor package 1000D according to an example embodiment may have the same or similar characteristics as those described with reference to FIGS. 1 to 6B, except that a plurality of semiconductor chips C1, C2, and C3 may be directly bonded and coupled (e.g., which may be referred to as hybrid bonding, direct bonding, or the like) without a separate connection member (e.g., a metal pillar, a solder bump, an adhesive film, or the like).

In an implementation, the plurality of semiconductor chips C1, C2, and C3 may include a lower insulating layer 111 surrounding a plurality of lower pads 104 and a plurality of upper insulating layers 121 surrounding the plurality of upper pads 105, respectively. The upper insulating layer 121 and the lower insulating layer 111, adjacent to each other, may include a first bonding layer BL1 and a second bonding layer BL2 bonded to each other. The first bonding layer BL1 and the second bonding layer BL2 may include a material that can be bonded and coupled to each other, e.g., silicon oxide (SiO) or silicon carbonitride (SiCN). The plurality of upper pads 105 and the plurality of lower pads 104, adjacent to each other, may include a material that can be bonded and coupled to each other, e.g., copper (Cu), nickel (Ni), gold (Au), silver (Ag), or an alloy thereof. A bonding surface BS formed by metal bonding by the plurality of upper pads 105 and the plurality of lower pads 104 and formed by dielectric bonding by the first bonding layer BL1 and the second bonding layer BL2 may be between the plurality of semiconductor chips C1, C2, and C3.

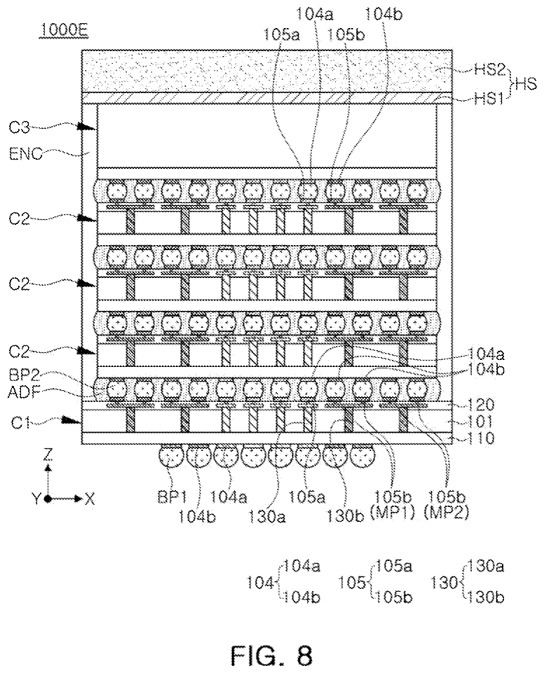

FIG. 8 is a cross-sectional view illustrating a semiconductor package 1000E according to an example embodiment.

Referring to FIG. 8, the semiconductor package 1000E according to an exemplary embodiment may have the same or similar characteristics as those described with reference to FIGS. 1A to 7B except for further including a heat dissipation structure HS on an encapsulant ENC.

The heat dissipation structure HS may help control warpage of the semiconductor package 1000E, and may help externally dissipate heat transferred from a second group of through-electrodes 130b. The heat dissipation structure HS may include a heat dissipation plate HS2 and an insulating heat conduction layer HS1 adhering the heat dissipation plate HS2 to the third semiconductor chip C3. The heat dissipation plate HS2 may include a material having excellent thermal conductivity, e.g., aluminum (Al), gold (Au), silver (Ag), copper (Cu), iron (Fe), graphite, graphene, or the like. In an implementation, the heat dissipation plate HS2 may have a plate shape. The insulating heat conduction layer HS1 may include a thermal interface material (TIM), e.g., a thermally conductive adhesive tape, thermally conductive grease, or thermally conductive adhesive.

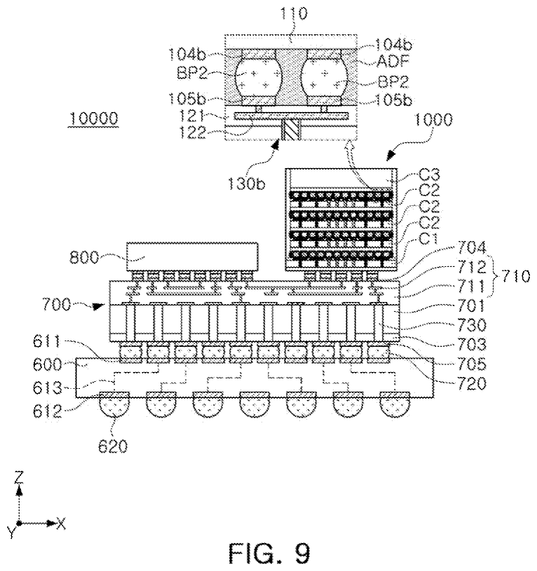

FIG. 9 is a cross-sectional view illustrating a semiconductor package 10000 according to an example embodiment.

Referring to FIG. 9, the semiconductor package 10000 according to an example embodiment may include a package substrate 600, an interposer substrate 700, at least one chip structure 1000, and a processor chip 800.

The chip structure 1000 may have characteristics, the same as or similar to those of the semiconductor packages 1000A, 1000B, 1000C, 1000D, 1000E, 1000a, 1000b, 1000c, 1000d, and 1000e, described with reference to FIGS. 1A to 8.

The package substrate 600 may be a support substrate on which the interposer substrate 700, the processor chip 800, and the chip structure 1000 are mounted, and may be a substrate for a semiconductor package including a printed circuit board (PCB), a ceramic substrate, a glass substrate, a tape wiring board, or the like.

A body of the package substrate 600 may include different materials depending on the type of substrates. In an implementation, when the package substrate 600 is a printed circuit board, it may be formed by additionally stacking an interconnection layer on one or both surfaces of a body copper-clad laminate or a copper-clad laminate.

The package substrate 600 may include a lower terminal 612, an upper terminal 611, and a redistribution circuit 613. The upper terminal 611, the lower terminal 612, and the redistribution circuit 613 may form an electrical path connecting a lower surface and an upper surface of the package substrate 600. The upper terminal 611, the lower terminal 612, and the redistribution circuit 613 may include a material, e.g., copper (Cu), aluminum (Al), nickel (Ni), silver (Ag), or gold (Au), platinum (Pt), tin (Sn), lead (Pb), titanium (Ti), chromium (Cr), palladium (Pd), indium (In), zinc (Zn), carbon (C), or an alloy containing two or more metals thereof. An external connection terminal 620 connected to the lower terminal 612 may be on the lower surface of the package substrate 600. The external connection terminal 620 may include tin (Sn), indium (In), bismuth (Bi), antimony (Sb), copper (Cu), silver (Ag), zinc (Zn), lead (Pb), or alloys thereof.

The interposer substrate 700 may include a substrate 701, a lower passivation layer 703, a lower pad 705, an interconnection structure 710, metal bumps 720, and through-vias 730. The chip structure PS and the processor chip 800 may be electrically connected to each other via the interposer substrate 700.

The substrate 701 may be formed of, e.g., silicon, organic, plastic, or glass. When the substrate 701 is a silicon substrate, the interposer substrate 700 may be referred to as a silicon interposer. In an implementation, when the substrate 701 is an organic substrate, the interposer substrate 700 may be referred to as a panel interposer.

The lower passivation layer 703 may be on a lower surface of the substrate 701, and a lower pad 705 may be below the lower passivation layer 703. The lower pad 705 may be connected to the through-via 730. The chip structure PS and the processor chip 800 may be electrically connected to the package substrate 600 through the metal bumps 720 disposed below the lower pad 705.

The interconnection structure 710 may be on an upper surface of the substrate 701, and may include an interlayer insulating layer 711 and a single-layer or multi-layer interconnection structure 712. When the interconnection structure 710 has a multi-layer interconnection structure, interconnection patterns of different layers may be connected to each other through contact vias.

The through-via 730 may extend from an upper surface to a lower surface of the substrate 701, and penetrate through the substrate 701. In an implementation, the through-via 730 may extend into the interconnection structure 710, and be electrically connected to interconnections of the interconnection structure 710. When the substrate 701 is silicon, the through-vias 730 may be referred to as TSVs. In an implementation, the interposer substrate 700 may include only interconnection structures therein and may not include through-vias.

The interposer substrate 700 may be used for the purpose of converting or transmitting an input electrical signal between the package substrate 900 and the chip structure PS or processor chip 800. Accordingly, the interposer substrate 700 may not include elements such as active elements or passive elements. In an implementation, the interconnection structure 710 may be below the through-via 730. In an implementation, a positional relationship between the interconnection structure 710 and the through-via 730 may be relative.

The metal bump 720 may electrically connect the interposer substrate 700 and the package substrate 900. The chip structure PS may be electrically connected to the metal bump 720 through interconnections of the interconnection structure 710 and the through-via 730. In an implementation, lower pads 705 used for power or ground may be integrated and connected to metal bumps 720, so that the number of lower pads 705 may be greater than the number of metal bumps 720.

The processor chip 800 may include, e.g., a central processor (CPU), a graphics processor (GPU), a field programmable gate array (FPGA), a digital signal processor (DSP), a cryptographic processor, a microprocessor, a microcontroller, an analog-digital converter, an application specific integrated circuit (ASIC), or the like.

In an implementation, the semiconductor package 10000 may further include a sealant covering the chip structure 1000 and the processor chip 800 on the interposer substrate 700. In an implementation, the semiconductor package 10000 may further include an outer sealant covering the interposer substrate 700 and the internal sealant on the package substrate 600. The outer sealant and the inner sealant may be formed together and may not be distinguishable. In an implementation, the semiconductor package 10000 may further include a heat dissipation structure covering the chip structure 1000 and the processor chip 800.

One or more embodiments may provide a semiconductor package having improved heat dissipation characteristics.

As set forth above, a semiconductor package having improved heat dissipation characteristics may be provided by introducing a through-electrode providing a heat dissipation path in a stacking direction of semiconductor chips.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor package, comprising:
a first semiconductor chip, at least one second semiconductor chip, and a third semiconductor chip, sequentially stacked in a vertical direction and electrically connected to each other;
an encapsulant on the first semiconductor chip, the encapsulant encapsulating at least a portion of each of the first semiconductor chip, the at least one second semiconductor chip, and the third semiconductor chip; and
a plurality of external connection bumps below the first semiconductor chip, the plurality of external connection bumps being electrically connected to the first semiconductor chip, the at least one second semiconductor chip, and the third semiconductor chip,
wherein:
the first semiconductor chip, the at least one second semiconductor chip, and the third semiconductor chip each include a plurality of lower pads,
the first semiconductor chip and the at least one second semiconductor chip each include:
a plurality of upper pads including a first group of upper pads and a second group of upper pads, and
a plurality of through-electrodes electrically respectively connecting the plurality of upper pads and the plurality of lower pads, and
the plurality of through-electrodes includes:
a first group of through-electrodes respectively connected to the first group of upper pads, and
a second group of through-electrodes connected to upper pads that are electrically connected to each other of the second group of upper pads.

2. The semiconductor package as claimed in claim 1, wherein a separation distance between through-electrodes of the second group of through-electrodes is equal to or greater than a separation distance between through-electrodes of the first group of through-electrodes.

3. The semiconductor package as claimed in claim 1, wherein the first group of through-electrodes are electrically insulated from the second group of through-electrodes.

4. The semiconductor package as claimed in claim 1, wherein:
the first group of through-electrodes includes signal electrodes, power electrodes, and ground electrodes, and
the second group of through-electrodes includes dummy electrodes.

5. The semiconductor package as claimed in claim 1, wherein:
the first semiconductor chip, the at least one second semiconductor chip, and the third semiconductor chip each further include a lower interconnection layer between the plurality of lower pads and the plurality of through-electrodes, and a lower insulating layer in which the lower interconnection layer is buried, and
the plurality of lower pads includes:
a first group of lower pads connected to the first group of through-electrodes by the lower interconnection layer, and
a second group of lower pads electrically insulated from the first group of lower pads.

6. The semiconductor package as claimed in claim 5, wherein the second group of through-electrodes are connected to at least one lower pad of the second group of lower pads by the lower interconnection layer.

7. The semiconductor package as claimed in claim 6, wherein the third semiconductor chip further includes dummy electrodes, each dummy electrode having one end electrically connected to the second group of lower pads and another end exposed at an upper surface of the third semiconductor chip.

8. The semiconductor package as claimed in claim 5, wherein the second group of lower pads includes a via portion extending into the lower insulating layer and electrically insulated from the lower interconnection layer.

9. The semiconductor package as claimed in claim 1, wherein:
the first semiconductor chip and the at least one second semiconductor chip each further include an upper interconnection layer between the plurality of upper pads and the plurality of through-electrodes, and an upper insulating layer in which the upper interconnection layer is buried, and
the second group of through-electrodes is connected to upper pads of the plurality of upper pads that are electrically connected to each other by the upper interconnection layer.

10. The semiconductor package as claimed in claim 1, wherein:
the first semiconductor chip and the at least one second semiconductor chip each further include an upper insulating layer surrounding upper portions of the plurality of through-electrodes, and in which the plurality of upper pads are disposed, and a pattern portion on the upper insulating layer and extending between upper pads of the plurality of upper pads that are electrically connected to each other, and
the second group of through-electrodes are connected to upper pads of the plurality of upper pads that are electrically connected to each other by the pattern portion.

11. The semiconductor package as claimed in claim 1, wherein the first semiconductor chip has a width that is greater than a width of the at least one second semiconductor chip and greater than a width of the third semiconductor chip.

12. The semiconductor package as claimed in claim 11, wherein the width of the at least one second semiconductor chip and the width of the third semiconductor chip are substantially the same.

13. The semiconductor package as claimed in claim 1, further comprising:
a plurality of interconnection bumps between the first semiconductor chip, the at least one second semiconductor chip, and the third semiconductor chip, the plurality of interconnection bumps being electrically connected to the plurality of through-electrodes; and
a plurality of adhesive films surrounding the plurality of interconnection bumps between the first semiconductor chip, the at least one second semiconductor chip, and the third semiconductor chip.

14. The semiconductor package as claimed in claim 1, wherein:
the first semiconductor chip, the at least one second semiconductor chip, and the third semiconductor chip each further include a lower insulating layer surrounding the plurality of lower pads and an upper insulating layer surrounding the plurality of upper pads, respectively, and
the plurality of upper pads and the upper insulating layer are in direct contact with the plurality of lower pads and the lower insulating layer, adjacent to each other in the vertical direction.

15. The semiconductor package as claimed in claim 14, wherein the lower insulating layer and the upper insulating layer each include a silicon oxide or a silicon carbonitride.

16. A semiconductor package, comprising:
a first semiconductor chip including a first group of through-electrodes, a second group of through-electrode around the first group of through-electrodes, a first group of upper pads electrically connected to the first group of through-electrodes, and a second group of upper pads electrically connected to the second group of through-electrodes;
a second semiconductor chip on the first semiconductor chip, the second semiconductor chip including a first group of lower pads electrically connected to the first group of upper pads and a second group of lower pads electrically connected to the second group of lower pads; and
a plurality of interconnection bumps between the first semiconductor chip and the second semiconductor chip, the plurality of interconnection bumps electrically connecting corresponding ones of the first group of upper pads and the first group of lower pads and corresponding ones of the second group of upper pads and the second group of lower pads,
wherein upper pads of the second group of upper pads, that are connected to each other, are connected to one through-electrode of the second group of through-electrodes.

17. The semiconductor package as claimed in claim 16, wherein the first group of upper pads is respectively connected to the first group of through-electrodes.

18. The semiconductor package as claimed in claim 16, wherein:
the upper pads of the second group of upper pads, that are connected to each other, are arranged in a matrix, and
on a plane, the one through-electrode of the second group of through-electrodes is in a center of the matrix.

19. The semiconductor package as claimed in claim 16, wherein:
the second semiconductor chip further includes a lower interconnection layer, and a lower insulating layer covering the lower interconnection layer, and
the second group of lower pads includes a via portion extending into the lower insulating layer.

20. A semiconductor package, comprising a plurality of semiconductor chips stacked in a vertical direction,
wherein:
at least one semiconductor chip among the plurality of semiconductor chips includes a substrate, a plurality of lower pads below the substrate, a plurality of upper pads on the substrate, and a plurality of through-electrodes penetrating through the substrate and electrically connected to at least one of the plurality of lower pads and the plurality of upper pads, and
the plurality of through-electrodes includes:
a first group of through-electrodes connected to one upper pad among the plurality of upper pads, and
a second group of through-electrodes connected to two or more upper pads among the plurality of upper pads.
